(19) United States
(12) Patent Application Publication
(10) Pub. No.: US 2006/0024227 A1
(43) Pub. Date: Feb. 2, 2006

(54) Array of single-walled carbon nanotubes and process for preparaton thereof

(76) Inventors: Shigeo Maruyama, Tokyo (JP); Yoichi Murakami, Tokyo (JP)

Correspondence Address: HOWSON AND HOWSON;ONE SPRING HOUSE CORPORATION CENTER, BOX 457, 321 NORRISTOWN ROAD, SPRING HOUSE, PA, 19477, US

(21) Appl. No.: 10/965,699

(22) Filed: Oct. 14, 2004

Related U.S. Application Data
(60) Provisional application No. 60/511,865, filed on Oct. 16, 2003.

(51) Int. Cl. D01F 9/12; B05D 1/12; C23C 16/00

(52) U.S. Cl. 423/447.3; 427/180; 427/248.1; 427/372.2

(57) ABSTRACT

An array of aligned single-walled nanotubes and a process of fabricating an array of aligned single-walled nanotubes comprising chemical vapour deposition in the presence of a gas flow, preferably a reducing atmosphere provided by a continuous Ar/H₂ gas flow. The SWNTs are preferably prepared on a quartz surface and are aligned normal to the surface.

### CROSS REFERENCE TO RELATED APPLICATIONS

This application claims the benefit of U.S. Provisional Patent Application No. 60/511,865 filed on Oct. 16, 2003.

### BACKGROUND OF THE INVENTION

The present invention relates to an ordered array of single-walled carbon nanotubes (SWNTs) and to a method of preparing an ordered array of SWNTs. The array may be formed in a direction normal to the substrate surface.

Single-walled carbon nanotubes (SWNTs) have unique properties such as quantum discreetness in the electron/phonon energy state and metal-semiconductor duality (R. Saito, G. Dresselhaus, M. S. Dresselhaus, Physical Properties of Carbon Nanotubes, Imperial College Press, London, 1998). Due to their novel electronic and thermal properties, SWNTs show great potential for use in a variety of applications, including chemical, mechanical and electrical applications (M. S. Dresselhaus, G. Dresselhaus, and P. Avouris, Carbon Nanotubes: Synthesis, Structure, Properties and Applications, (Springer, Berlin, 2001) and S. Tatsuura et al., Adv. Mater. 15, 534 (2003)). Most of these properties are not observed in multi-walled carbon nanotubes (MWNTs). Considerable effort has been made to align SWNTs in one direction, but only MWNTs have so far been vertically grown on a flat surface (B. Q. Wei et al., Nature 416, 495 7 (2002)). Mechanical alignment of SWNTs in a direction parallel to the substrate surface (E. Joselevich et al., Nano Lett. 2, 1137 (2002) and J. E. Fischer et al., J. Appl. Phys. 93, 2157 (2003)) has been proposed and in one study the vertical alignment of SWNT fragments by a chemical modification approach has been proposed (Z. Liu et al., Langmuir 16, 3569 (2000)). However all these studies have employed sonically shortened SWNT fragments made from SWNTs produced in bulk and such fragments suffer from poor uniformity in density and thickness. It would be advantageous if SWNTs could be ordered without the possibility of degeneration produced by such mechanical and chemical processes.

### SUMMARY OF THE INVENTION

We have found that high-density alignment of SWNTs on a substrate surface (particularly a quartz surface) can be achieved by a thermal catalytic chemical vapour deposition (CCVD) process. The array may be ordered with the SWNTs extending normal to the substrate surface.

In one aspect the invention provides an array of SWNTs formed on a substrate surface wherein the array is aligned in a direction normal to the substrate surface.

In a further aspect the invention provides a process for fabricating an ordered array of single walled nanotubes comprising:
providing a substrate;
depositing an array of mono-dispersed bimetallic catalyst particles on a surface of the substrate, and
heating the substrate surface supporting said array of mono-dispersed bimetallic catalyst particles in the presence of an carbonvapour to grow an array of SWNTs substantially normal to the substrate surface.

The process for growing the SWNTs is a thermal CCVD process. A flow of a reducing gas, such as an Ar/H₂ gas mixture, may be provided during the CCVD reaction. The gas flow may be continuous during the CCVD reaction.

The step of depositing an array of mono-dispersed bimetallic catalyst particles on a surface of the substrate may comprise:
coating the substrate surface with a solution containing organic salts of at least two metals that form the bimetallic catalyst;
oxidising the metal salts to form a bimetallic oxide layer on the substrate; and
heating the substrate supporting the bimetallic oxide layer in the presence of a reducing gas, wherein the temperature in said heating step is increased up to a deposition temperature at a ramp rate of about 25° C./min to form said dense array of mono-dispersed bimetallic catalyst particles on the surface of the substrate.

Specific examples of organic salts include metal alkoxides and salts of organic acids. Particularly preferred salts are salts of organic acids particularly carboxylates and most preferred salts are acetate salts.

As used herein the term “normal to the substrate surface” is intended to mean that a majority of the SWNTs extend away from the substrate surface. The term is not intended to be restricted to SWNTs that grow at exactly 90 degrees to the substrate surface. Indeed, not all of the SWNTs in the ordered array need to grow normal to the substrate surface provided that a majority of the fibres are oriented substantially normal to the substrate surface. Also, depending on the length of the SWNTs, a free end of some of the SWNTs may not be oriented substantially normal to the substrate surface. The SWNTs generally form a film in which most of the SWNTs are aligned normal to the substrate surface.

### BRIEF DESCRIPTION OF THE DRAWINGS

FIG. 1 is a schematic diagram showing the configuration of a chemical vapour deposition (CVD) apparatus suitable for use in the processes of the present invention.

FIG. 2 is a schematic diagram showing steps of the processes of the present invention.

FIG. 3 shows (A) Quartz substrates before CVD on which catalyst was loaded (left) and after CVD on which a vertically aligned SWNT film was synthesized (right). Upper left corner of the substrate was held during the spin-coat process and therefore did not contact with the metal acetate solution. (B) SEM image of vertically aligned SWNTs grown directly on quartz surface by the CVD performed flowing 300 sccm of Ar/H₂, which was taken from 20° tilted angle from horizon. (C) SEM image of non-aligned SWNTs grown without the flow of Ar/H₂, which was taken from 20° from vertical. The partial peel-off of the SWNT film is intentional to emphasize its morphology and thickness.

FIG. 4 is a TEM image of vertically aligned SWNTs removed by sonicating the substrate in methanol for 15 s. (A) Typical image of flakes of SWNT film retaining the alignment that were occasionally observed. (B) A higher magnification image of the flake that is made up of SWNT bundles. The inset indicates location of enlarged area with a solid square.

FIG. 5 is Raman spectra taken by 488 nm excitation laser for the (A) vertical aligned specimen exhibited in FIGS. 2(A), and (B) non-aligned specimen in FIG. 2(B). For the calculation of diameter distribution from RBM peaks the correlation ‘d (nm)=248/u(cm-1)’ (d: diameter, u: Raman shift) proposed by Jorio et al. (Phys. Rev. Lett. 86, 1118 (2001)) was used.

FIG. 6 shows (A) Optical absorption of the quartz substrates on which (i) non-aligned and (ii-iv) aligned SWNTs were grown, where incident light of randomly polarized was used. The tilt angle of substrate toward an incident light was attached to each spectrum. Asterisks denote our measurement system-oriented peaks. (B) Angular dependences of optical transmittances normalized by those at 0°. The 488 nm laser with linear polarized was used to test both of s-polarization (left) and p-polarization (right) cases. The specimen examined were a quartz substrate with (i) catalyst only, (ii) non-aligned SWNTs, (iii) vertically aligned SWNTs, and (iv) HiPco SWNTs dispersed with Gum Arabic solution and pasted/dried on a raw quartz substrate prepared as previously described (R. Bandyopadhyahya et al., Nano Lett. 2, 25 (2002)). Fitted curves denote theoretical angular dependences of transmittance for both s- and p-polarized cases when n=1.5 and 1.7.

FIG. 7 shows SEM images of growth of aligned SWNT films after (a) 15 seconds, (b) 3 min, (c) 10 min, and (d) 100 min. Vertical growth of bundles occurs early on, causing alignment of the SWNT film. The film thickness exceeds 4 μm. The scale bar applies to all images.

FIG. 8 is a plot showing the optical absorbance at 633 nm (left axis) and film thickness measured by SEM (right axis) as a function of growth time. The absorbance follows a similar trend as the film thickness except at the initial growth stage below 3 min.

FIG. 9 shows SEM images of vertically aligned SWNTs.

FIG. 10 is a schematic description of the relationship between the laser propagation direction (k), the laser light polarization direction (e), and the SWNT axis direction (l).

FIG. 11 shows schematically the configuration of resonance Raman scattering.

FIG. 12 shows schematically the configuration of resonance Raman scattering.

FIG. 13 shows RBM spectra measured by 488, 514.5, and 633 nm lasers for different incident configuration (i-iv, see below). G⁺ band spectra taken at 488 nm are also shown. The RBM spectra were normalized by the corresponding G⁺ height and decomposed into Lorentzian curve by maintaining the FWHM values within a spectrum. Asterisks denote the peaks dominantly observed in parallel polarization condition. (i) from top, (ii) perpendicular, (iii) 45°, (iv) parallel configurations.

FIG. 14 shows plots showing the change in intensities of selected RBM for measurement angles of “from top” to “45°” to “parallel” conditions for (a) 488 and (b) 514.5 nm. The ordinate was normalized by the values of the “from top” condition.

### DETAILED DESCRIPTION OF THE INVENTION

Although the following detailed description contains many specifics for the purposes of illustration, a person of ordinary skill in the art will appreciate that many variations and alterations to the following details are within the scope of the invention. Accordingly, the following examples of embodiments of the invention are set forth without any loss of generality to, and without imposing limitations upon, the claimed invention.

SWNT Growth and Preparation of Arrays of SWNTs

Using the processes of the present invention, arrays of SWNTs on a substrate surface are formed by depositing an array of mono-dispersed bimetallic catalyst particles on the substrate surface, and forming SWNTs in a catalytic chemical vapour deposition process by exposing the substrate surface to a ethanol vapour whilst heating the substrate surface to grow an array of SWNTs substantially normal to the substrate surface.

In this specification the terms vertical and vertically are used to refer to an array of SWNTs extending substantially normal to the substrate surface.

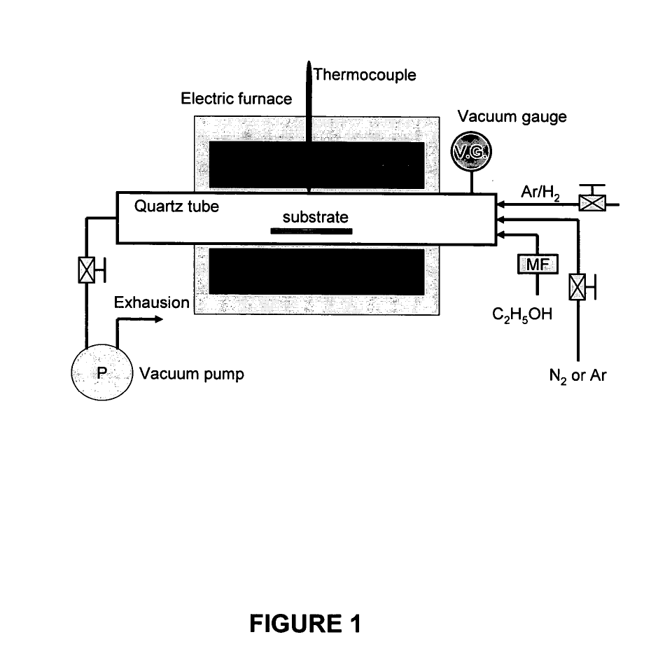

The configuration of a chemical vapour deposition (CVD) apparatus of the type suitable for use in the processes of the present invention is shown in FIG. 1.

The system comprises an electric furnace, a quartz tube (chamber), gas/source material supply lines, a vacuum pump, a pressure gauge and valves. The furnace contains a thermocouple, the head of which contacts the outside of the quartz tube. A mass flow controller is installed in the ethanol supply line and an ethanol vaporizer is attached before mass-flow controller. A quartz substrate with a Co/Mo bimetal catalyst is set at the center of the heading zone within the chamber.

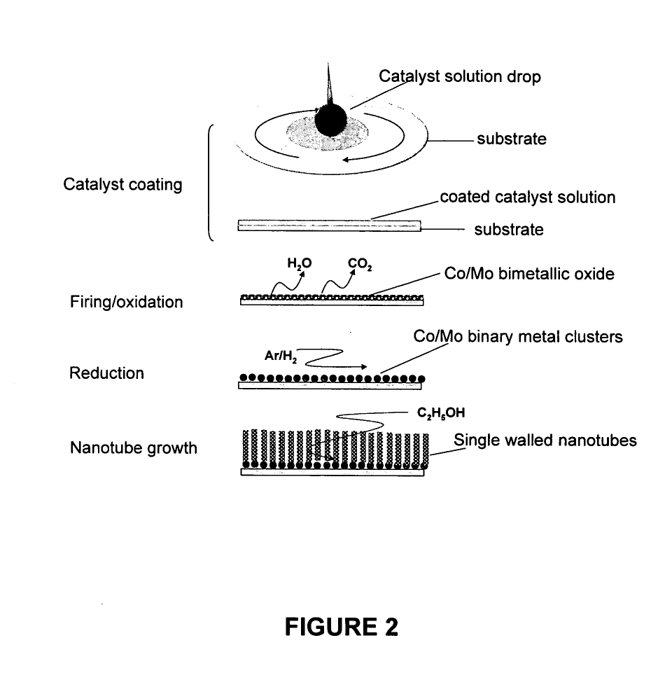

Details of a preferred SWNT deposition process are shown schematically in FIG. 2 (see also M. Hu et al., J. Catal. 225, 230 (2004) which is incorporated herein in its entirety). In a first step of the process, a substrate is provided. The substrate material may be selected from the group consisting of quartz, indium-tin oxide, titanium oxide, sapphire, aluminum oxide, zirconium oxide, iridium oxide, ruthenium oxide, nickel oxide, tungsten oxide, platinum, silver, iridium, titanium, tungsten, nickel, ruthenium. Most preferably, the substrate is a quartz substrate.

A surface of the substrate is then coated with a solution containing salts (preferably carboxylate salts such as acetate salts) of at least two metals that form the bimetallic catalyst. The solution containing acetate salts may be coated onto the substrate surface using any suitable technique that is known in the art, such as spin-coating or dip-coating. Preferably, the solution is spin-coated onto the substrate.

The bimetallic catalyst may be selected from the group consisting of Co/Mo, Ni/Mo, Fe/Mo, Co/W, Ni/W, Fe/W, Co/Ni/Mo, Co/Fe/Mo, Ni/Fe/Mo, Co/Fe/Ni/Mo, Co/Ni/W, Ni/Fe/W, and Co/Fe/W. Preferably, the bimetallic catalyst is Co/Mo. It will appreciated that as used herein the term “bimetallic catalyst” is intended to include catalysts formed from two or more metals. The solution containing salts such as acetate salts of the metal catalysts is therefore a solution of acetate salts of metals of any one of the aforementioned combinations. Most prreferably, the solution is an ethanol solution containing Co acetate and Mo acetate.

Next, the metal salts are oxidised to form a bimetallic oxide layer on the substrate. Preferably, the coated substrate is heated in air or oxygen at about 400° C. for about 30 min., to form the bimetallic oxide layer. Preferably, the bimetallic oxide layer is a Co/Mo oxide layer.

The substrate with the bimetallic oxide layer is then heated in the presence of a reducing gas to form a dense array of mono-dispersed bimetallic catalyst particles on the surface of the substrate. To do this the substrate with the bimetallic oxide layer can be placed in a CVD chamber such as the one shown in FIG. 1. The substrate is set at the center of the heating zone. An inert gas such as N₂, He or Ar is introduced into the chamber to expel air, and the chamber is then exhausted by a vacuum pump. After exhausting the chamber, the back pressure in the chamber reaches less than about 10⁻³ Torr and the back pressure is kept at less than about 10⁻³ Torr for about 30 min.

Next, a reducing gas is introduced into the chamber at a flow rate of about 20 SCCM, and the temperature of the electric furnace is increased toward a deposition temperature of from about 600° C. to about 900° C. at a ramp rate of about 25° C./min. Preferably, the deposition temperature is about 800° C. Preferably, the reducing gas is a mixture of hydrogen and an inert gas, such as Ar/H₂, N₂/H₂ and He/H₂. A preferred reducing gas is an Ar/ H₂ mixture. During this process step, the bimetallic oxide layer is transformed into fine bimetallic particles with a diameter of around 2 nm which act as nucleation sites of the SWNTs. The density of the obtained fine metallic particles is high and as a result the SWNTs can not grow laterally on the substrate surface. Therefore, they grow in a direction that is substantially normal to the substrate.

When the deposition temperature is reached, the reducing gas is replaced with a carbon containing vapour which leads to the deposition and growth of SWNTs. The vapour of carbon containing molecules may be a one or more of: methanol, ethanol, propanol, butanol, hexanol or acetone vapor. Preferably, the carbon containing vapour is ethanol vapour.

During deposition of the SWNTs, the pressure of the carbon containing vapour is maintained at a reduced pressure of from 1 Torr to 200 Torr. Preferably, the carbon containing vapour is maintained at about 20 Torr. Alternatively, the deposition can carried out with a mixture of carbon containing vapour and the reducing gas to form SWNTs of similar quality to those formed using carbon containing vapour alone.

In practice, it is found that if the bimetallic oxide layer is not reduced completely, SWNTs do not grow vertically since the bimetallic particle nucleation site density is too low. Therefore, complete formation of highly dense bimetallic particles by the reducing agent is necessary to provide for optimal vertical growth of SWNTs.

The process of the present invention produces a dense film of vertically aligned SWNTs and their bundles directly on quartz surfaces through a thermal CVD process. The selectivity toward SWNTs is almost 100% and the quality of the SWNTs is high according to TEM and Raman analyses.

Arrays of SWNTs formed on a substrate surface wherein the array is aligned in a direction normal to the substrate surface can be used in various applications including optical (Y. -C. Chen et al., Appl. Phys. Lett. 81, 975 (2002)) and sensing (J. Li et al., Nano Lett. 3, 929 (2003) and S. Ghosh et al., Science 299, 1042 (2003)) devices recently proposed by using deposited SWNTs made by a post processing of bulk-produced SWNTs. The process of the present invention is also suitable to produce SWNTs with nearly constant lengths that are defined by the thickness of the SWNT film. This may be especially desired when SWNTs are to be used as electrical components.

Characterisation of Vertically Grown SWNTs

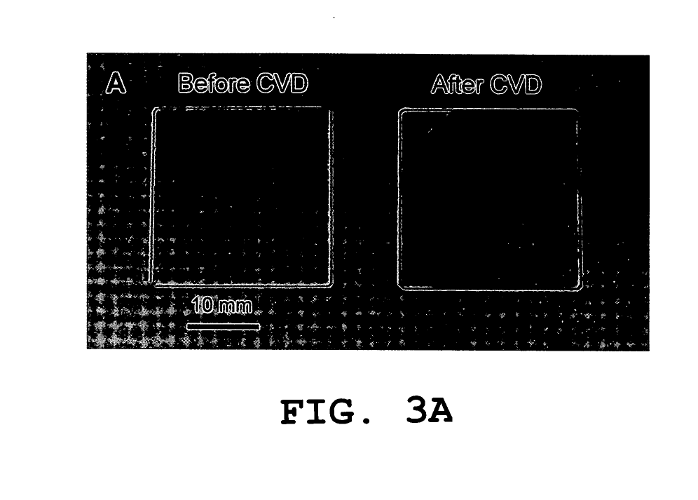

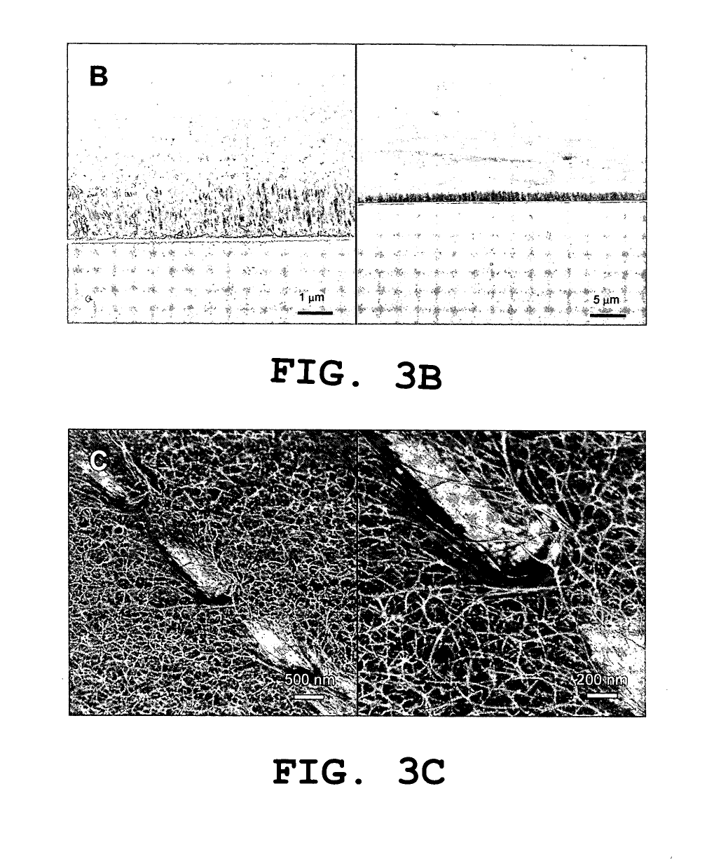

FIG. 3 shows the quartz substrate before and after CVD. While the former on which catalyst has been mounted retains full transparency, the latter is blackened with SWNTs. The substrate was broken and a fresh broken edge was observed from the lateral direction by scanning electron microscopy (SEM). As shown in FIG. 3B in different magnifications, the SWNTs (or their bundles) form an ordered array with the SWNTs extending substantially normal to the substrate surface with a thickness of about 1.5 μm. When no reducing gas (such as Ar/H₂) flow is used during CVD process, the morphology of the SWNTs is usually that shown in FIG. 3C where bundles of SWNTs grow parallel to the surface. Partial peeling of the SWNT film in the pictures is intentional to emphasize the thickness and morphology of SWNTs.

The reproducibility of the alignment of the SWNTs substantially normal to the substrate surface has been confirmed. We attribute this alignment to an enhanced growth rate and resultant higher density of SWNTs caused by continuous H₂ reduction. It is thought that, as a result of the continuous H₂ reduction, the SWNTs are only allowed to grow in a direction away from the substrate due to interference with neighbouring bundles.

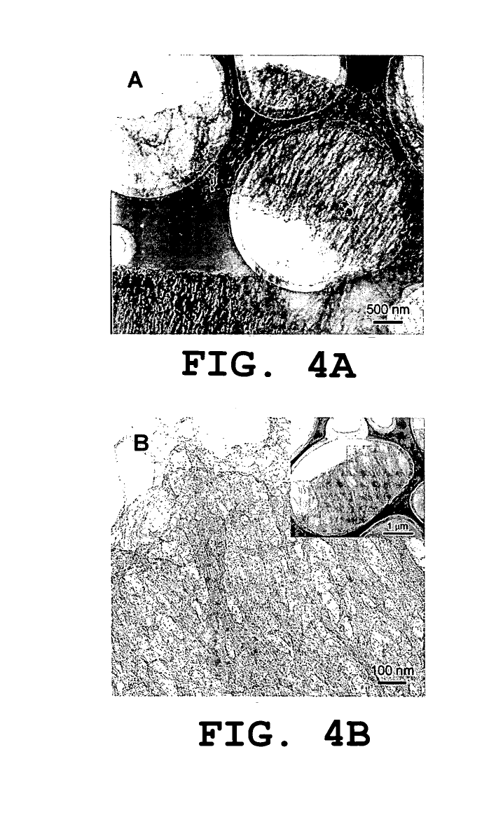

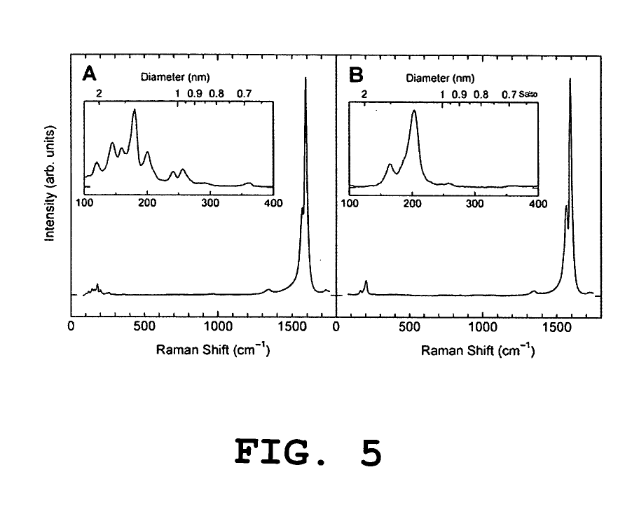

We further observed this specimen using transmission electron microscopy (TEM) by sonicating the array in methanol for 15 s and depositing a drip of the solution on a carbon-deposited microgrid. In addition to unravelled SWNT bundles, an apparent vestige of the aligned film was occasionally observed as shown in FIG. 4. In the magnified picture in FIG. 4B, it is confirmed that bundles of SWNTs are aligned and catalytic particles of 2-3 nm (should be metal carbide) are sparsely mixed among the SWNTs. It is clear that the length of SWNTs is nearly equal to that of the SWNT film observed in FIG. 4B. No MWNTs or double-walled nanotubes have been observed in repeated observations. The high quality of the SWNTs shown in FIGS. 4B and 4C was confirmed by corresponding Raman scattering analyses with 488 nm excitation exhibited in FIGS. 5A and 5B, respectively. The spectra also showed the vertically aligned case (FIG. 5A) has wider diameter distribution compared to the case without alignment (FIG. 5B).

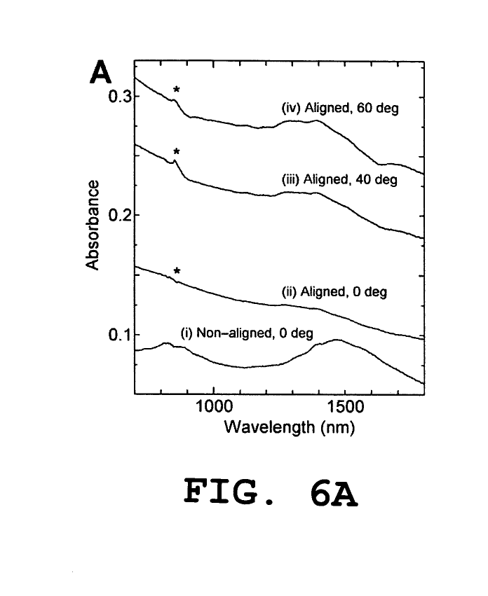

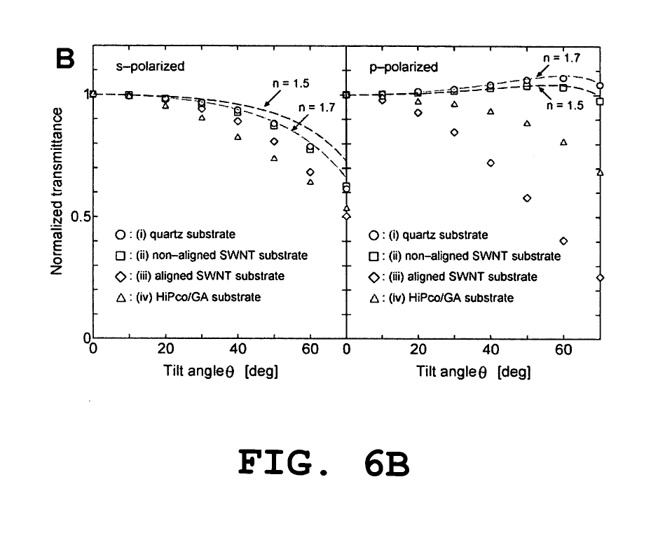

With a film of SWNTs aligned normal to the substrate surface, an anisotropy in the optical properties was expected. FIG. 6A shows optical absorption spectra for specimens (i) without alignment and (ii-iv) with alignment measured with randomly polarized light. In the case without alignment, an absorption peak corresponding to semiconducting band gap Eₛ¹¹ is observed at 1400-1600 nm while no distinct peak is seen in the case of aligned SWNTs (FIG. 6A(ii)). However, once this is placed in a certain angle to the incident light, the Eₛ¹¹ starts to emerge in the broader range of 1300-1700 nm, which may be due to wider diameter distribution observed in FIG. 5. This angular dependence of absorption can be regarded as a manifestation of specimen anisotropy in the normal direction.

We further performed an optical absorption measurement using a linearly polarized 488 nm laser. The absorption is maximized when the direction of polarization coincides with the axis of SWNTs. The laser beam was expanded into about 5 mm spot size light using a collimator before an incidence into the specimen held in a specified angle, and then the transmitted light was converged with a convex lens on a laser power sensor. FIG. 6B compares the angular dependences of normalized transmittances for the quartz substrates with (i) oxidized catalyst only, (ii) non-aligned SWNT layer, (iii) aligned SWNT layer, and (iv) a dried film of HiPco (M. J. Bronikowski et al., J. Vac. Sci. Technol. A 19, 1800 (2001)) SWNTs prepared by coating HiPco-dispersed Gum Arabic solution (R. Bandyopadhyaya et al., Nano Lett. 2, 25 (2002)). The absolute transmittances at θ=0 are (i) 0.93, (ii) 0.76, (iii) 0.61, and (iv) 0.23, respectively. In the figures, the predicted transmittance for s- and p-polarizations Tₛ and Tₚ are shown which were calculated from well-known formulae:

$${T}_{s} = 1 - {( \frac{{n}_{2} cos {θ}_{2} - {n}_{1} cos {θ}_{1}}{{n}_{2} cos {θ}_{2} + {n}_{1} cos {θ}_{1}} )}^{2} , {T}_{p} = 1 - {( \frac{{n}_{2} / cos {θ}_{2} - {n}_{1} / cos {θ}_{1}}{{n}_{2} / cos {θ}_{2} + {n}_{1} / cos {θ}_{1}} )}^{2}$$

where n₁, n₂, θ₁, and θ₂ denote refractive indices of air and solid, and propagating angles in both media from normal of the solid plane, respectively. Although n of glass is about 1.5, the calculation best fitted to the plot in FIG. 6B(i) when n=1.7 was employed. This shift is considered to partially arise from the metallic oxides loaded on the quartz surface. In the case of non-aligned SWNTs, the transmittances in both s- and p-polarization exhibit close tendency to that of FIG. 6B(i). In contrast, despite only 15% lower transmittance from the non-aligned specimen at θ=0, the aligned sample (FIG. 6B(iii)) exhibits remarkably different tendency in p-polarization case where an optical cross-section or SWNTs length component in the direction of polarization increases according to sin θ. Finally, in the case of HiPco film dispersed in Gum Arabic (FIG. 6B(iv)), where the transmittance at θ=0 is lowest among all cases, shows almost the same net transmittance for both polarizations. This implies the dominance of geometrical scattering in addition to isotropic absorption of incident light. From above comparison, in addition to the fact that only in the case of aligned SWNTs the transmittance in p- is lower than that in s-polarization, it is clear that the optical abnormality of FIG. 6B(iii) is a representation of the alignment of SWNTs.

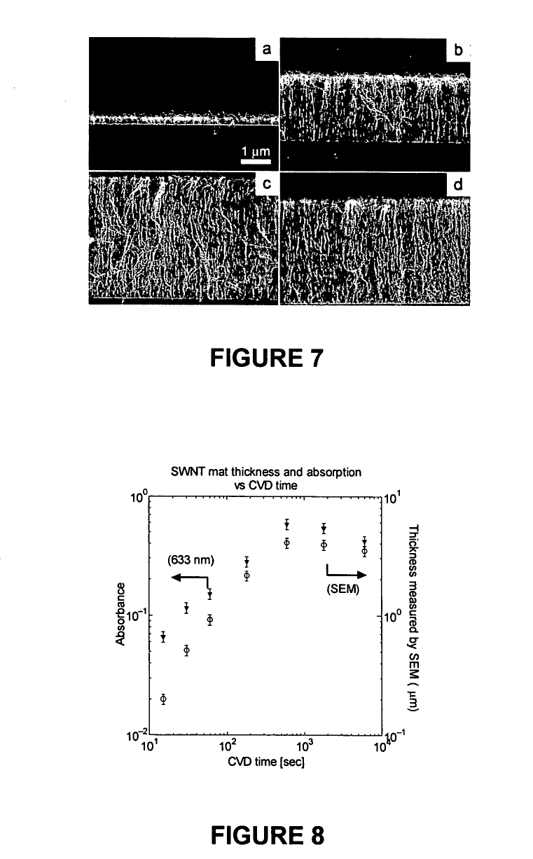

A series of time-progressive images taken at various growth times are shown in FIG. 7. In the first several seconds of growth, SWNT's form bundles with neighbouring tubes. In FIG. 7(a) significant bundling can be seen after only 15 seconds. At this stage, the tubes are not yet well aligned, but are clearly standing rather than growing along the surface. This initial vertical growth is understood to result because a high local tube density restricts the growth in all lateral directions, so that the only direction in which SWNTs are free to grow is perpendicular to the substrate surface. This results in vertical alignment. The film is approximately 200 nm thick, but much longer bundles can be seen extending above the film. After 3 minutes of growth (FIG. 7(b)) the SWNT film is more than 2 μm thick, and is aligned perpendicular to the substrate surface. After 10 minutes of growth (FIG. 7(c)) the aligned film is more than 4 μm thick, but after 30 min (not shown) we found an unexpected decrease to only 3.9 μm, and after 100 min (FIG. 7(d)) the film thickness is only 3.5 μm.

Optical absorbance measurements were also performed on the aligned SWNT films. The relationship between absorbance, film thickness measured from SEM images, and growth time is plotted in FIG. 8. A decrease of the absorbance after long deposition times agrees with the measured decrease of the SWNT film thickness, and although the growth rate is obviously non-linear a correlation can be seen between the film thickness and the absorbance. Based on this relationship it may be possible to determine the thickness of an aligned SWNT film simply by measuring its absorbance. Such a measurement may not only determine the average film thickness over a relatively large area, but its non-destructive nature is desirable for quality control purposes in a production process. In situ absorbance measurements performed during SWNT growth may also be used for precise control of the film thickness.

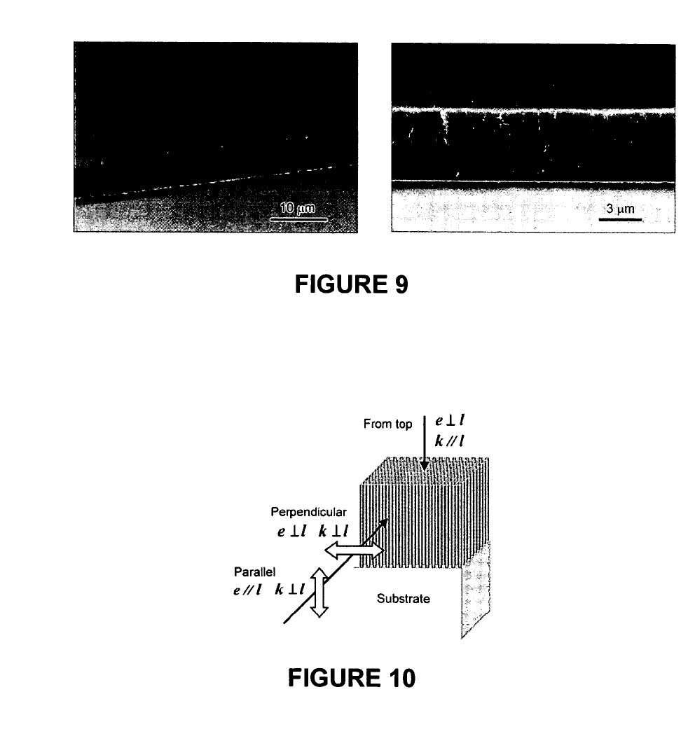

FIG. 9 shows cross-sectional SEM images of vertically aligned SWNT. The film thickness is around 5 μm and aligned bundles are clearly visible. The bundles typically have diameter of approximately 15 nm. The overall density of SWNTs has been estimated to be around 1.0×10¹⁷/m² (Y. Murakami et al., Chem. Phys. Lett. 385, 298 (2004)). According to TEM measurements, this specimen has a diameter varying from 0.8 nm to 3.0 nm., with an average diameter dₐᵥ of 1.9 nm and a standard deviation of σ=0.5 to 0.4 nm. Therefore, cross-sectional SEM images of vertically aligned SWNT are the bundles which consist of several SWNTs.

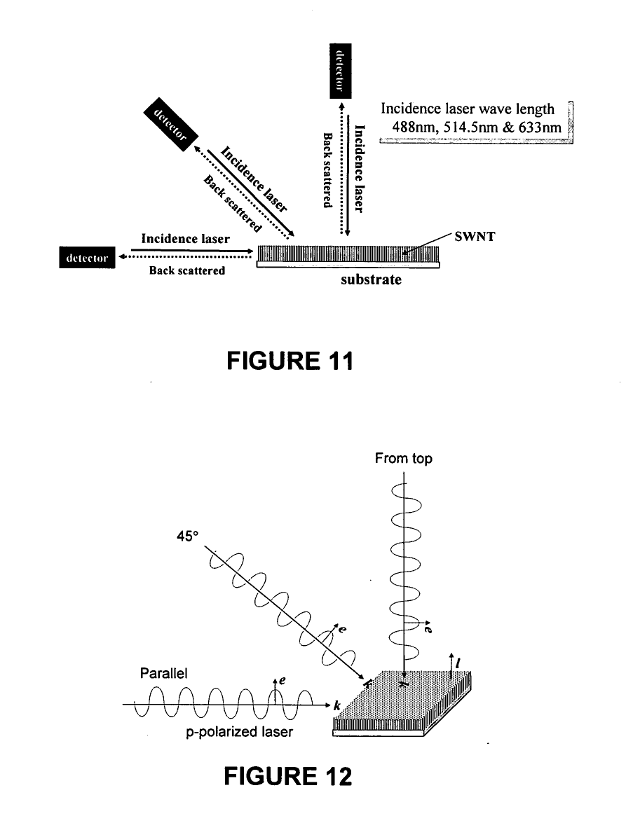

As shown in schematic form in FIG. 11, we used four different configurations of the laser propagation direction (k), the laser polarization direction (e), and the SWNT axis direction (/). The “From top” configuration is k/// and e⊥/, where the laser is incident perpendicular to the substrate (or the SWNT film). In the “perpendicular” and “parallel” configurations, the relationships are {k⊥/ and e⊥/} and {k⊥/ and e///}, respectively, and “45°” configuration the angle between e and | is 45° while maintaining k⊥|.

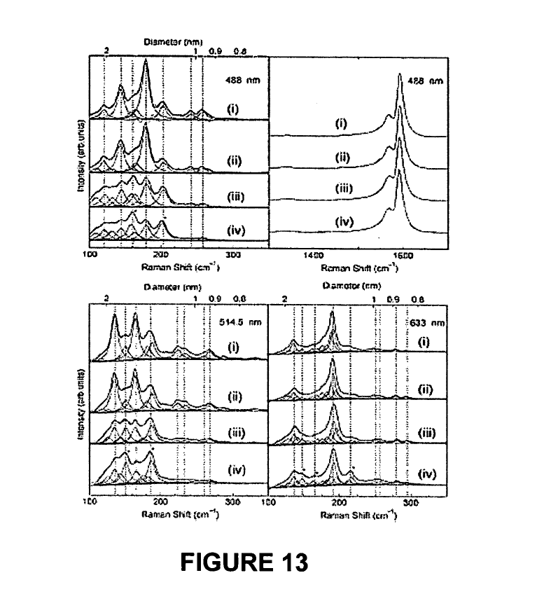

FIG. 13 shows RBM spectra taken in (i) from top, (ii) perpendicular, (iii) 45°, and (iv) parallel configuration for 488 nm, 514.5 nm, and 633 nm laser wavelengths. In the 488 nm case, the high frequency spectra including D and G⁺ bands are also shown. All the RBM peaks were normalized by the height of G+ band at 1593 cm-1. At each wavelength, the spectra of cases (i) and (ii) {where e⊥/} show the same shape while that of case (iv) {where e///} exhibits a remarkably different spectra shape. The spectra in case (iii) lie in the intermediate between (i) and (iv). It is clear that some peaks are observed with certain intensities only in the e⊥/ case and diminish in the e/// configuration, while the other group behaviour oppositely. This is especially remarkable for the 488 and 514.5 nm case.

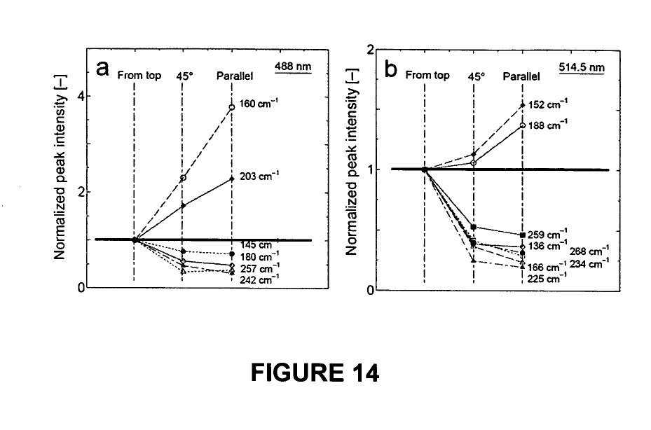

FIGS. 14(a) and (b) show the change of selected peak intensity of the RBM spectra for the measurement angles of the “from top” to “45°” to “parallel” conditions for 488 and 514.5 nm. The ordinate for each peak is normalized by the value in the case of “from top”, to show the group behaviour of the RBM peaks toward the polarization. The collective peak at 185 cm⁻¹ for 514.5 nm is decomposed into two adjacent peaks of 183 and 188 cm⁻¹. Although some ambiguity remains in the quantitative decomposition, we recognized the 188 cm-1 peak to be e/// peak based on FIG. 13. The peaks apparently associated with the e/// configuration for 488 and 514.5 nm are {160 and 203 cm⁻¹} and {152 and 188 cm⁻¹}, respectively.

In summary, the RBM spectrum patterns are drastically changed depending on the incidence angles against substrate when the vertically aligned SWNTs are measured by p-polarized laser.

### EXAMPLE

In one embodiment of the invention, a quartz substrate was spin-coated into a Co-Mo acetate solution (both 0.01 wt % in ethanol), which supported the catalyst. The catalyst was oxidized by heating the spin-coated substrate in air at 400° C., and then reduced by a flowing Ar/H₂ mixture (3% H₂) during heating of the CVD chamber. Catalyst prepared by this method resists agglomeration at the growth temperature (800° C.), resulting in mono-dispersed catalyst particles with diameters of 1-2 nm that are densely deposited (˜10¹⁷ m⁻²) on the substrate surface. When the CVD chamber reached 800° C. the Ar/H₂ mixture was stopped and ethanol vapor was introduced at a pressure of 10 Torr to initiate growth. Although hydrogen can be used as a catalyst activator during the CVD method, we have also found that hydrogen was unnecessary, and that SWNTs grown in the absence of hydrogen were better aligned and in higher yield those grown with hydrogen.

While the present invention has been described by the reference to the above-mentioned embodiments, certain modifications and variants will be evident to those of ordinary skill in the art.

What is claimed is:

1. A process for fabricating an ordered array of single walled nanotubes, comprising the steps of:
providing a substrate;
depositing an array of mono-dispersed bimetallic catalyst particles on a surface of the substrate; and
heating the substrate supporting said array of mono-dispersed bimetallic catalyst particles in the presence of a carbon vapour to grow an array of single walled nanotubes substantially normal to the substrate surface.

2. The process according to claim 1 wherein the array of mono-dispersed bimetallic catalyst particles are densely deposited whereby lateral growth of single walled nanotubes is inhibited.

3. The process according to claim 1 wherein a flow of reducing gas is provided during the step of growing the single walled nanotubes.

4. The process according to claim 1 wherein the step of depositing an array of mono-dispersed bimetallic catalyst particles on a surface of the substrate comprises:
coating the substrate surface with a solution containing salts of at least two metals that form the bimetallic catalyst;
oxidising the metal salts to form a bimetallic oxide layer on the substrate; and
heating the substrate supporting the bimetallic oxide layer in the presence of a reducing gas, wherein the temperature in said heating step is increased up to a deposition temperature at a ramp rate of about 25° C./min to form said dense array of mono-dispersed bimetallic catalyst particles on the surface of the substrate.

5. The process according to claim 4 wherein said solution containing acetate salts of metals that form the bimetallic catalyst is spin coated onto the substrate surface.

6. The process according to claim 4 wherein the salts are Co and Mo salts.

7. The process according to claim 3 wherein the salts of at least two metals are selected from metal salts wherein the counter ion are selected from the group consisting of alkoxides and organic acids.

8. The process according to claim 7 wherein the counter ions are acetate.

9. The process according to claim 4 wherein the step of oxidising the metal salts comprises heating said coated substrate to about 400° C. in the presence of air or oxygen.

10. The process according to claim 4 wherein said reducing gas is an argon/hydrogen mixture.

11. The process according to claim 4 wherein said step of forming single walled nanotubes comprises exposing the substrate supporting said array of mono-dispersed bimetallic catalyst particles to a carbon vapour under reduced pressure at a deposition temperature higher than 500° C.

12. The process according to claim 11 wherein said deposition temperature is from 600° C. to 900° C.

13. The process according to claim 11 wherein said deposition temperature is about 800° C.

14. The process according to claim 11 wherein said carbon vapour is ethanol vapour.

15. The process according to claim 14 wherein the ethanol pressure is from 1 Torr to 200 Torr.

16. The process according to claim 14 wherein the ethanol pressure is about 20 Torr.

17. An array of single walled nanotubes formed on a substrate surface wherein the array is aligned in a direction substantially normal to the substrate surface.

18. The array according to claim 16 wherein the single walled nanotubes are grown on a substrate surface supporting an array of mono-dispersed bimetallic catalyst particles.

19. The array according to claim 16, wherein said single walled nanotubes are bundled and a ratio of the length of the bundles from the substrate surface to a free end of the bundles (H) and the width of the bundles (W) is H/W≧5 as determined by SEM or TEM.

20. The array according to claim 16, wherein the array shows an increase in peak intensities at 160 cm⁻¹ and 203 cm⁻¹, and the decrease of the peak intensities at 145 cm⁻¹, 180 cm⁻¹ 257 cm⁻¹ & 242 cm⁻¹ when the incidence angle is changed from “from top” to “parallel” for an incidence p-polarized 488 nm laser.

21. The array according to claim 16, wherein the array shows an increase in peak intensities at 152 cm⁻¹ and 188 cm⁻¹ and the decrease of the peak intensities at 259 cm⁻¹, 136 cm⁻¹ 268 cm⁻¹, 234 cm⁻¹, 166 cm⁻¹, & 225 cm⁻¹ when the incidence angle is changed from “from top” to “parallel” for an incidence p-polarized 514.5 nm laser.
